(19) United States
(12) Patent Application Publication
(10) Pub. No.: US 2010/0287078 A1
(43) Pub. Date: Nov. 11, 2010

(54) ACCUMULATOR FOR PASSENGER CARS AND COMMERCIAL VEHICLES

(76) Inventors: Jan-Michael Graehn, Stuttgart (DE); Ian Faye, Stuttgart (DE)

Correspondence Address: RONALD E. GREIGG;GREIGG & GREIGG P.L.L.C., 1423 POWHATAN STREET, UNIT ONE, ALEXANDRIA, VA, 22314, US

(21) Appl. No.: 12/679,714

(22) PCT Filed: Aug. 12, 2008
(86) PCT No.: PCT/EP08/60568

§ 371 Date: May 6, 2010

(30) Foreign Application Priority Data
Sep. 25, 2007 (DE) 102007045633.8

(51) Int. Cl. H01M 10/48; B60K 1/00; G06Q 30/00; G01R 19/00; G06F 19/00

(52) U.S. Cl. 705/34; 180/65.31; 702/60

(57) ABSTRACT

An accumulator for passenger cars or commercial vehicles, including a device for storing electric energy, two electric connecting devices, in particular connecting contacts, for electrically connecting the device for storing electric energy to an electric drive motor, provides a financial incentive for the user for moderate handling of the accumulator. Such a task is achieved in that at least one sensor is configured for detecting measurement data in regard to the electric current and/or the electric voltage of the accumulator taken from and/or fed to the accumulator and/or the temperature of the accumulator and/or the installation time and/or the electric current time of the accumulator.

The present invention relates to an accumulator for passenger cars or commercial vehicles, including a device for storing electrical energy, and two electrical connecting devices, in particular connecting contacts, for electrically connecting the device to an electric drive motor. The invention also relates to a passenger car or commercial vehicle having an accumulator and an electric drive motor that is supplied with electric current by the accumulator and to an apparatus for an electric filling station for ascertaining the level of a billing amount for changing an accumulator in a passenger car or commercial vehicle. The invention furthermore relates to a method for ascertaining the usage-dependent costs of using an accumulator in a passenger car or commercial vehicle.

In passenger cars or commercial vehicles, internal combustion engines are currently predominantly used for converting the chemical energy, stored in hydrocarbons, such as gasoline, diesel, natural gas, or alcohol, into mechanical energy for the propulsion of the passenger car or commercial vehicle. Fossil fuel sources and growing areas for biofuels are limited, so that current from regenerative energy sources, such as wind, sunlight and water, are gaining ever-increasing importance for driving passenger cars or commercial vehicles. The electric accumulators available now and expected to be available in the foreseeable future have a low energy density, so that at a moderate size and weight of the accumulators, only a relatively short range of a passenger car or commercial vehicle is attainable, compared to passenger cars or commercial vehicles with internal combustion engines.

The range of application of passenger cars or commercial vehicles with electric drives is therefore considered to be limited to locally defined regions, such as a town or metropolitan area, with daily travel distances of less 150 km. The mobility available in passenger cars or commercial vehicles with internal combustion engines even over greater distances cannot be attained with accumulators, because of the low energy density and the long charging time. To achieve greater mobility even with passenger cars or commercial vehicles with electric drives, fully-charged accumulators in readiness at electric filling stations can be exchanged for an empty or almost empty accumulator of a passenger car or commercial vehicle with an electric drive, so that the disadvantageous long charging times of accumulators have no significance.

Electric accumulators age, and with time, losses occur, so that the utility and useful capacity and the maximum electrical power of the accumulator decrease. Charging and discharging accumulators generally causes heat losses; that is, the accumulator heats up. High withdrawal powers cause greater losses than low withdrawal powers. The aging mechanisms of the accumulator are accelerated by high withdrawal powers and high temperatures. An accumulator user who demands high powers from the accumulator will damage the accumulator more than a user who draws only slight and moderate powers. Moreover, both losses and a shortening of the service life of the accumulator can be amplified as a result of a deep discharge.

The success of an accumulator changing system for passenger cars or commercial vehicles with electric drives depends on the operating costs that occur. Improper use and discharge of the accumulators by the user causes high costs for the operator of an accumulator changing system, and these costs must also be borne by those who use accumulators moderately. High costs for the accumulators can make an accumulator changing system unproductive.

The object of the present invention is therefore to make an accumulator, a passenger car or commercial vehicle, an apparatus for an electric filling station for ascertaining the level of the billing amount for changing an accumulator in a passenger car or commercial vehicle, and a method for ascertaining the usage-dependent costs of the use of an accumulator in a passenger car or commercial vehicle available that all give the user a financial incentive to use the accumulator moderately.

This object is attained with an accumulator for passenger cars or commercial vehicles, including a device for preferably chemical storage of electrical energy, two electrical connecting devices, in particular connecting contacts, for electrically connecting the device for storing electrical energy to an electric drive motor, in which at least one sensor is embodied for detecting measurement data regarding the current drawn from and/or delivered to the accumulator, particularly as a function of time, and/or the voltage of the accumulator, particularly as a function of time, and/or the temperature of the accumulator, particularly as a function of time, and/or the installed time and/or the current time. The current drawn from and/or delivered to the accumulator, the voltage of the accumulator, and/or the temperature of the accumulator can thus be measured preferably as a function of time. In addition, the maximum or minimum temperature, voltage or current can for instance be measured. Thus the parameters of the usage characteristic of the accumulator can be detected.

In a further embodiment, preferably by means of predetermined criteria and/or functions, with an evaluation unit, from the measurement data of the at least one sensor, the charge status of the accumulator and/or the accumulator performance and/or the losses of the accumulator are ascertainable as profile data.

Accumulators for passenger cars or commercial vehicles for storing electrical energy are in general accumulators which store electrical energy by means of chemical reactions. Besides these, accumulators that store energy in physical ways, such as capacitors, can also be considered.

The accumulator performance or state of health (SOH) of an accumulator is ascertained in the evaluation unit as a function of the measurement data. The rated capacity of the accumulator is the maximum possible capacity of the accumulator. In use of the accumulator, only a portion of the rated capacity, such as 80% of it, should be used; that portion is the useful capacity of the accumulator. The accumulator performance, that is, the actual useful capacity and/or rated capacity of an accumulator, decreases from use; losses in the useful capacity and/or rated capacity of the accumulator occur. The usage characteristic is determined for instance from the parameters of withdrawal and/or feedback of an electrical power; duration of withdrawal and/or feedback of an electrical power; converted electrical energy, that is, the sum of the electrical energy drawn and delivered; charge status, in particular the undershooting of a minimum charge status; temperature of the accumulator; duration of a temperature of an accumulator; installed time; and current time. From these parameters, the actual accumulator performance is ascertained; that is, the evaluation unit, for instance with criteria and/or functions stored in memory, can determine the losses of the accumulator from the parameters of the usage characteristic that are detected by the sensors, and can determine the actual accumulator performance from the difference in the accumulator performance before installation and during or after installation in a passenger car or commercial vehicle.

In a further feature, the profile data ascertained by the evaluation unit and/or the measurement data ascertained from the at least one sensor can be stored in a memory unit.

In a supplementary embodiment, preferably by means of predetermined criteria and/or functions, the usage-dependent costs for use of the accumulator in a passenger car or commercial vehicle can be ascertained in the evaluation unit from the profile data and/or the measurement data. The charge status of the accumulator, the accumulator performance, the losses of the accumulator, or the usage characteristic are thus assessed in financial terms. Preferably, the usage characteristic, that is, the measurement data, are assessed financially on the basis of predetermined criteria and/or functions. For instance, exceeding a defined electrical withdrawal power per unit of time, or exceeding the predetermined maximum installed time per day, costs a certain amount of money.

Moreover, the financial cost from losses of the accumulator, that is, the difference in the accumulator performance before and during or after installation, can be determined. To that end, the evaluation unit also has data available on the accumulator performance before the installation of the accumulator.

Expediently, at least one data transmission means is present, for forwarding the profile data and/or the measurement data to an apparatus for ascertaining the level of the billing amount for changing the accumulator and/or to a display device in the passenger car or commercial vehicle and/or to the evaluation device.

In particular, a display device is present for displaying the profile data and/or the measurement data and/or the usage-dependent costs. The user can thus learn not only the actual measurement data and profile data but also the usage-dependent data and can orient his style of driving accordingly.

The task is furthermore attained with a passenger car or commercial vehicle having an accumulator and an electric drive motor that is supplied with current by the accumulator, in which at least one sensor is embodied for detecting measurement data regarding the current drawn from and/or delivered to the accumulator, in particular as a function of time, and/or the voltage of the accumulator, in particular as a function of time, and/or the temperature of the accumulator and/or the installed time, in particular as a function of time, and/or the current time of the accumulator.

Expediently, preferably by means of predetermined criteria and/or functions, with an evaluation unit, from the measurement data of the at least one sensor, the charge status of the accumulator and/or the accumulator performance and/or the losses of the accumulator are ascertainable as profile data.

Preferably, the profile data ascertained by the evaluation unit and/or the measurement data ascertained by the at least one sensor can be stored in a memory unit.

In a further feature, preferably by means of predetermined criteria and/or functions, from the profile data and/or the measurement data, usage-dependent costs for use of the accumulator in a passenger car or commercial vehicle can be ascertained in the evaluation unit.

In a supplementary embodiment, at least one data transmission means is present, for forwarding the profile data and/or the measurement data to an apparatus for ascertaining the level of the billing amount for changing the accumulator and/or to a display device in the passenger car or commercial vehicle and/or to the evaluation device.

In a further embodiment, a display device is embodied for displaying the profile data and/or the usage-dependent costs and/or the measurement data of the accumulator.

The above descriptions of the accumulator of the invention apply analogously to the passenger car or commercial vehicle of the invention.

The object is furthermore attained with an apparatus for an electric filling station or an apparatus of an electric filling station for ascertaining the level of a billing amount for changing an accumulator in a passenger car or commercial vehicle, in which at least one data receiving means and/or at least one data input means is embodied for receiving and/or inputting profile data regarding the charge status of the accumulator and/or the accumulator performance and/or the losses of the accumulator and/or measurement data regarding the current drawn from and/or delivered to the accumulator and/or the voltage of the accumulator and/or the temperature of the accumulator and/or the installed time and/or the current time of the accumulator; and in an assessment unit, usage-dependent costs can be ascertained from the profile data and/or the measurement data.

The above comments on the accumulator of the invention apply analogously to the apparatus of the invention for an electric filling station for ascertaining the level of a billing amount for changing an accumulator in a passenger car or commercial vehicle, in which the assessment unit corresponds to the evaluation unit.

The object is further attained with a method for ascertaining the usage-dependent costs of using an accumulator in a passenger car or commercial vehicle, having the following steps: detecting measurement data regarding the current drawn from and/or delivered to the accumulator in particular as a function of time and/or the voltage of the accumulator in particular as a function of time and/or the temperature of the accumulator in particular as a function of time and/or the installed time and/or the current time of the accumulator, using at least one sensor; preferably storing the measurement data in a memory unit; ascertaining the usage-dependent costs in an evaluation unit or an assessment unit from the measurement data by means of predetermined criteria and/or functions. The usage-dependent costs are thus ascertained in the evaluation unit or the assessment unit as a function of a measurement data by means of preferably predetermined criteria and/or functions.

In a further feature, preferably by means of predetermined criteria and/or functions, the charge status of the accumulator and/or the accumulator performance and/or the losses of the accumulator are ascertained as profile data from the measurement data in an evaluation unit or an assessment unit. The charge status of the accumulator and/or the accumulator performance and/or the losses of the accumulator as profile data are thus ascertained in an evaluation unit or an assessment as a function of the measurement data, preferably by means of predetermined criteria and/or functions. The charge status of the accumulator before installation is known to the evaluation or assessment unit.

In particular, from the profile data, current times are ascertained in the evaluation unit or assessment unit by means of predetermined criteria and/or functions.

Expediently, the measurement data and/or the profile data are forwarded to an apparatus for an electric filling station for ascertaining the level of a billing amount for changing an accumulator in a passenger car or commercial vehicle.

In an expanded embodiment, the measurement data and/or the profile data and/or the current times are displayed in a display device. The user of a passenger car or commercial vehicle can thus obtain information about the usage characteristic, the accumulator performance, and the costs caused by him.

An exemplary embodiment of the invention will be described below in further detail in conjunction with the accompanying drawings.

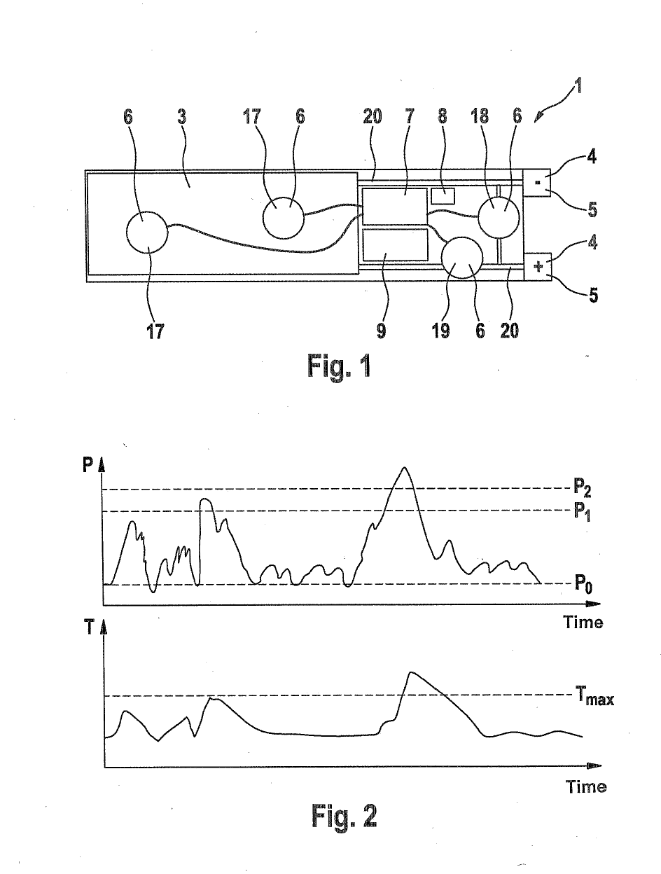

FIG. 1 shows a schematic view of an accumulator with an evaluation unit;

FIG. 2 shows two line graphs, of an electrical power drawn from the accumulator and a temperature of the accumulator, each plotted on an ordinate, as a function of the time, each plotted on the abscissa; and

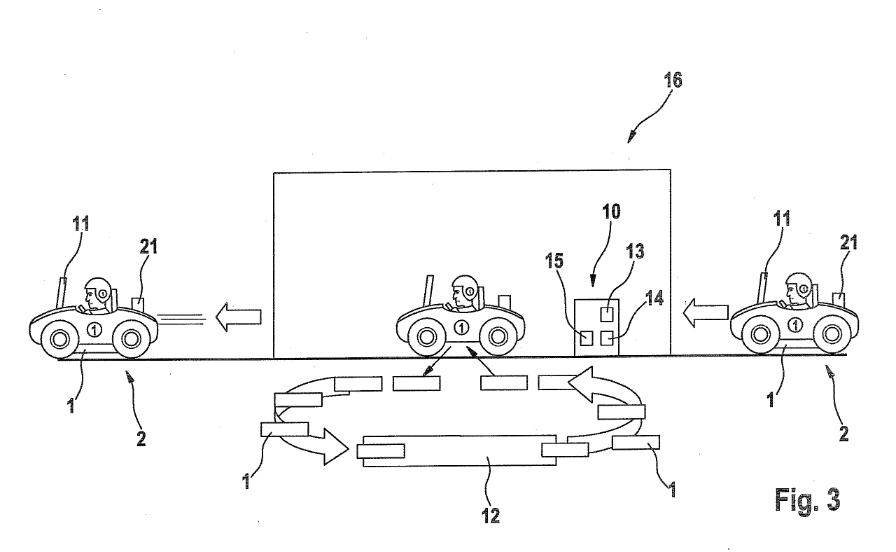

FIG. 3 is a schematic view of a passenger car and an electric filling station.

In FIG. 1, an accumulator 1 for storing electrical energy for a passenger car 2 is shown. Such accumulators 1 for supplying an electric drive motor 21 (FIG. 3) of a passenger car 2 with current generally have a useful capacity of at least 10 kWh and preferably at least 20 kWh. The maximum electrical power of these accumulators is for instance at least 20 kW and preferably at least 40 kW, so as to have enough driving power available for the passenger car 2. A lithium battery or lithium polymer battery can be considered, for example, for the accumulator 1.

The accumulator 1 has a device 3 for chemical storage of current or energy. Electrical lines 20 connect the device 3 to two connecting devices 4, embodied as connecting contacts 5. The current from the device 3 can be carried on (not shown) to the electric drive motor 21 of the passenger car 2 to the two connecting contacts 5 that have a − pole and a + pole. Sensors 6 can measure the temperature of the device 3, the current drawn from the device 3, and the voltage made available by the device. To that end, temperature sensors 17 are mounted on the outside of the accumulator 1. A voltage measuring device 18 and a current measuring device 19 are accordingly present in the lines 20. The temperature sensors 17, voltage measuring device 18, and current measuring device 19, as sensors 6, 17, 18, 19, forward measurement data to the electronic evaluation unit 7. There is also a sensor 6, not shown, in the electronic evaluation unit 7, for ascertaining the length of use of the accumulator 1. The term length of use is understood to mean the time that the accumulator 1 spends in the passenger car 2 (installed time) as well as the time that the accumulator 1 is used for drawing current and/or for feeding back current (current time).

The electronic evaluation unit 7, from the measurement data ascertained by the sensors 6, 17, 18, 19, calculates the charge status or state of charge (SOC) and the accumulator performance or state of health (SOH). The charge status of the accumulator 1 before installation in the passenger car 2 is known to the electronic evaluation unit 7. Data regarding the charge status and the accumulator performance are designated as profile data. For ascertaining the accumulator performance, the usage characteristic is employed.

The usage characteristic determines the losses of the accumulator 1, that is, a reduced usage and/or rated capacity and/or a reduced maximum electrical power of the accumulator 1. Losses of the accumulator 1 reduce the accumulator performance. The higher the losses, the lower the accumulator performance. The assessment of the losses is done with loss points; the more loss points are found, the higher are the losses of the accumulator. In general, the number of loss points is directly proportional to the losses of the accumulator. High withdrawal powers, such as 80% or 90% of the maximum electrical power, cause higher losses than slight or moderate withdrawal powers, such as 40% or 50% of the maximum electrical power of the accumulator 1. The period of time over which high or low withdrawal losses are found must also be taken into account. The usage characteristic of an accumulator 1 is thus related to the withdrawal power, or the ratio of the withdrawal power to the maximum electrical power, and to the time file a particular electrical power is being drawn.

In FIG. 2, in the upper graph, the electrical power P drawn is plotted on the ordinate, and in the lower graph, the temperature T of the accumulator 1 is plotted as a function of the time, which is plotted on the abscissa. A first power stage P₁ and a second power stage P₂ as well as the power stage P₀ are plotted as dashed horizontal straight lines in the upper graph. The power stage P₀ means that no electrical power is drawn from the accumulator 1. However, the curve extends partly below the power stage P₀, which means that the accumulator 1 is charged during the installed time, for instance by recuperative braking; that is, the electric drive motor 21 of the passenger car 2, on braking, acts as an electric generator, and the accumulator 1 is thus charged. The power stage P₁ amounts for instance to 65% of the maximum electrical power, and the power stage P₂ amounts for instance to 80% of the maximum electrical power of the accumulator 1. The duration of withdrawal of an electrical power above the power stage P₂ is assessed with more loss points than the duration above the power stage P₁. In this way, the current time of an accumulator 1 is assessed. Instead of using two power stages P₁, P₂, it is also possible for only one or for at least three power stages to be used for ascertaining the usage characteristic. A continuously variable assessment of the electrical power withdrawn is also possible (not shown) by means of functions, such as integrals, stored accordingly in the evaluation unit 7; the area, that is, the electrical power, above one or more power stages can be assessed.

In addition to or as a replacement to the electrical power withdrawn, in accordance with the lower graph in FIG. 2 the temperature T of the device 3 can also be used to ascertain the usage characteristic. The longer the temperature is above a temperature stage Tₘₐₓ, such as 45° C., the more loss points are allocated. Moreover, a plurality of temperature stages or a continuously variable assessment of the temperature can also be performed (not shown) by means of stored functions, such as integrals.

Losses also occur at accumulators 1 when current is not being withdrawn, outside the current time, so that the installed time is also assessed with loss points.

Losses also occur in accumulators 1 from the return or feedback of current, for instance in recuperative braking or on charging from the electrical system at home. These losses can be assessed (not shown) with loss points analogously to the withdrawal of current, for instance by means of power stages or in continuously variable fashion.

The electrical energy converted by the accumulator 1, that is, the sum of the electrical energy withdrawn and the electrical energy delivered, can also be assessed with loss points. For instance, the converted electrical energy can be assessed beyond the magnitude of at least one useful capacity of the accumulator or the assessment can be done continuously variably (not shown).

Moreover, undershooting the minimum charge status is also assessed with loss points as part of the usage characteristic. The more and/or the longer the minimum charge status of the accumulator 1 is undershot, the more loss points are allocated. The assessment of the undershooting of the minimum charge status of the accumulator 1 can be done (not shown) with one or more undershooting stages or in continuously variable fashion.

The measurement data and profile data and the loss points are stored in memory in a memory unit 8 and the usage-dependent costs are ascertained by the evaluation unit 7. A data transmission means 9 can forward the measurement data and profile data, the loss points, and the usage-dependent costs to a display device 11 by means of a radial or cable connection. The display device 1 can be disposed either on the accumulator 1 (not shown) or can be positioned within the view of the driver of the passenger car 2 (FIG. 3), for instance on the dashboard, or the display is done with existing display means in the interior of the passenger compartment (not shown). The driver of the passenger car 2 can thus, while driving, become informed of the actual measurement data and profile data and can learn the usage-dependent costs of his driving style. For instance, the actual costs can be indicated per kWh, to the extent that the costs for changing the accumulator 1 in an electric filling station 16 are known, or certain costs can be assumed.

In FIG. 3, an electric filling station 16 is shown. The data transmission means 9 can forward the measurement data by a radial or cable connection to a data receiving means 13 of an apparatus 10 for ascertaining the level of the billing amount for changing the accumulator 1 in an electric filling station 16 (FIG. 3). Moreover, with a data input means 14, the measurement data can additionally be input manually at the apparatus 10. From the measurement data, the usage-dependent costs are calculated in an assessment unit 15 of the apparatus 10. A passenger car 2 thus drives to the electric filling station 16 with an empty accumulator 1, replaces the empty accumulator 1 at the electric filling station with a full accumulator 1, and pays a certain price for that. The level of the price takes into account the usage characteristic as well, including the undershooting of the minimum charge status. The empty accumulators 1 are charged in a charging station 12.

In a system for changing accumulators 1, the tasks of the electric filling station 16 are replacing the empty accumulators 1 with full accumulators 1 in the passenger car 2, charging the empty accumulators 1, furnishing accumulators 1 that have a certain minimum accumulator performance and a certain minimum useful capacity as well as a minimum rated capacity, calibrating the measurement data and profile data of an empty accumulator 1 and a full accumulator 1, and issuing a bill that takes into account the residual useful capacity of the accumulator 1, the useful capacity of the new accumulator 1, and the accumulator performance. Moreover, if a minimum accumulator performance or a minimum state of health (SOH) is undershot, accumulators 1 are removed from the changing system and disposed of or recycled.

An accumulator with a range of approximately 150 km for the passenger car 2 should furnish 20 kWh of useful capacity. In a moderate driving style, from 20% to 80% of the rated capacity should be used. Aging must be taken into account, as well, so that in moderate accumulator operation, only 60% of the rated capacity should be allowed to be used. The accumulator must therefore have a rated capacity of 33.3 kWh, in order to have a useful capacity of 20 kWh in moderate use available.

For this accumulator 1, the electric filling station 16 can make the following specifications: Avoid temperatures of over 40° C. for the device 3 and in general, not drawing any electrical powers greater than 35 kW (P₁) and 45 kW (P₂) from the accumulator 1.

The accumulator 1 was in use by the user for 18 days; that is, the installed time is 18 days. For each day of the installed time, a certain amount is billed. The power stage P₁ and the power stage P₂ were exceeded for certain lengths of time. 24% of the rated capacity of the accumulator 1 is still available. The amounts ascertained by the apparatus 10 can be summarized as follows:

| | |
|---|---|
| Flat fee for accumulator changing service | 6.00 Euros |
| Residual charge 4% (=24% − 20%) | −1.65 Euros |
| Undershooting the minimum load state | 0.00 Euros |
| Overshooting the power stage P₁ | 1.90 Euros |
| Overshooting the power stage P₂ | 3.10 Euros |
| Installed time 18 days | 1.80 Euros |
| Furnishing a full accumulator that has 20 | 12.00 Euros |
| kWh of useful capacity | |
| Total: | 23.15 Euros |

Overall, with the present invention, for accumulators 1 for passenger cars 2, the operating costs of an accumulator changing system can be lowered, because the individual is billed not only for furnishing a new accumulator 1 or a certain useful capacity but additionally for the losses or reductions in the accumulator performance that are due to his driving style. Thus the individual is induced to use the accumulators 1 moderately, which reduces the overall costs of the accumulator changing system and enhances its acceptance.

1-16. (canceled)

17. An accumulator for passenger cars or commercial vehicles, including:
a device for storing electrical energy;
two electrical connecting devices, in particular connecting contacts, for electrically connecting the device to an electric drive motor; and
at least one sensor embodied for detecting measurement data regarding the current drawn from and/or delivered to the accumulator and/or the voltage of the accumulator and/or the temperature of the accumulator and/or the installed time and/or the current time of the accumulator.

18. The accumulator as defined by claim 11, wherein with an evaluation unit, from the measurement data of the at least one sensor, a charge status of the accumulator and/or accumulator performance and/or losses of the accumulator are ascertainable as profile data.

19. The accumulator as defined by claim 18, wherein the profile data ascertained by the evaluation unit and/or the measurement data are storable in a memory unit.

20. The accumulator as defined by claim 18, wherein from the profile data and/or the measurement data, usage-dependent costs can be ascertained in the evaluation unit.

21. The accumulator as defined by claim 18, further including at least one data transmission means for forwarding the profile data and/or the measurement data to an apparatus for ascertaining a level of a billing amount for changing the accumulator and/or to a display device in the passenger car or commercial vehicle and/or to the evaluation unit.

22. The accumulator as defined by claim 19, further including at least one data transmission means for forwarding the profile data and/or the measurement data to an apparatus for ascertaining a level of a billing amount for changing the accumulator and/or to a display device in the passenger car or commercial vehicle and/or to the evaluation unit.

23. The accumulator as defined by claim 18, wherein a display device is present for displaying the profile data and/or the measurement data and/or usage-dependent costs.

24. The accumulator as defined by claim 19, wherein a display device is present for displaying the profile data and/or the measurement data and/or usage-dependent costs.

25. A passenger car or commercial vehicle having:
an accumulator and an electric drive motor that is supplied with current by the accumulator; and
at least one sensor embodied for detecting measurement data regarding the current drawn from and/or delivered to the accumulator and/or a voltage of the accumulator and/or a temperature of the accumulator and/or an installed time and/or a current time of the accumulator.

26. The passenger car or commercial vehicle as defined by claim 25, wherein with an evaluation unit, from the measurement data of the at least one sensor, a charge status of the accumulator and/or accumulator performance and/or losses of the accumulator are ascertainable as profile data.

27. The passenger car or commercial vehicle as defined by claim 25, wherein the profile data ascertained by the evaluation unit and/or the measurement data are storable in a memory unit.

28. The passenger car or commercial vehicle as defined by claim 26, wherein from the profile data and/or the measurement data, usage-dependent costs can be ascertained in the evaluation unit.

29. The passenger car or commercial vehicle as defined by claim 26, further having at least one data transmission means for forwarding the profile data and/or the measurement data to an apparatus for ascertaining a level of a billing amount for changing the accumulator and/or to a display device in the passenger car or commercial vehicle and/or to the evaluation unit.

30. The passenger car or commercial vehicle as defined by claim 27, further having at least one data transmission means for forwarding the profile data and/or the measurement data to an apparatus for ascertaining a level of a billing amount for changing the accumulator and/or to a display device in the passenger car or commercial vehicle and/or to the evaluation unit.

31. The passenger car or commercial vehicle as defined by claim 26, wherein a display device is present for displaying the profile data and/or the measurement data and/or usage-dependent costs.

32. The passenger car or commercial vehicle as defined by claim 27, wherein a display device is present for displaying the profile data and/or the measurement data and/or usage-dependent costs.

33. An apparatus for an electric filling station for ascertaining the level of a billing amount for changing an accumulator in a passenger car or commercial vehicle, comprising:
at least one data receiving means and/or at least one data input means embodied for receiving and/or inputting profile data regarding a charge status of the accumulator and/or accumulator performance and/or losses of the accumulator and/or measurement data regarding a current drawn from and/or delivered to the accumulator and/or a voltage of the accumulator and/or a temperature of the accumulator and/or an installed time and/or a current time of the accumulator; and
an assessment unit, in which usage-dependent costs can be ascertained from the profile data and/or the measurement data.

34. A method for ascertaining the usage-dependent costs of using an accumulator in a passenger car or commercial vehicle, having the following steps:
detecting measurement data regarding a current drawn from and/or delivered to the accumulator and/or a voltage of the accumulator and/or a temperature of the accumulator and/or an installed time and/or a current time of the accumulator, using at least one sensor;
storing the measurement data in a memory unit; and
ascertaining usage-dependent costs in an evaluation unit or an assessment unit from the measurement data by means of predetermined criteria and/or functions.

35. The method as defined by claim 34, wherein a charge status of the accumulator and/or accumulator performance and/or losses of the accumulator are ascertained as profile data from the measurement data in the evaluation unit or the assessment unit.

36. The method as defined by claim 35, wherein the measurement data and/or the profile data are forwarded to an apparatus for an electric filling station for ascertaining a level of a billing amount for changing an accumulator in a passenger car or commercial vehicle.
